(19) United States
(12) Patent Application Publication
(10) Pub. No.: US 2017/0194138 A1
(43) Pub. Date: Jul. 6, 2017

(54) LOW TEMPERATURE SELECTIVE DEPOSITION EMPLOYING A GERMANIUM-CONTAINING GAS ASSISTED ETCH

(71) Applicants: International Business Machines Corporation, Armonk, NY (US); Matheson Tri-Gas, Inc., Basking Ridge, NJ (US)

(72) Inventors: Paul D. Brabant, Scodack, NY (US); Keith Chung, Guilderland, NY (US); Hong He, Schenectady, NY (US); Devendra K. Sadana, Pleasantville, NY (US); Manabu Shinriki, Longmont, CO (US); Yunpeng Yin, Schenectady, NY (US); Zhengmao Zhu, Poughkeepsie, NY (US)

(21) Appl. No.: 14/984,845

(22) Filed: Dec. 30, 2015

(51) Int. Cl. H01L 21/02; H01L 21/225; H01L 21/306

(52) U.S. Cl. CPC H01L 21/0262; H01L 21/30604; H01L 21/02524; H01L 21/2253

(57) ABSTRACT

A selective semiconductor deposition process that employs an alternating sequence of a deposition step and an etch step. During each deposition step, a semiconductor material is deposited on single crystalline surfaces at a greater deposition rate than on insulator surfaces. A combination of hydrogen chloride and a germanium-containing gas is employed within each etch step. The germanium-containing gas is employed to enhance the etch rate of hydrogen chloride, thereby enabling an effective etch process at temperatures as low as 380° C. Deposited semiconductor material is removed from above insulator surfaces, while a fraction of the deposited semiconductor material remains on semiconductor surfaces after each etch step, thereby providing a selective deposition of the semiconductor material.

### BACKGROUND

The present disclosure generally relates to a method of forming semiconductor structures, and more particularly to a method for low temperature selective deposition employing a germanium-containing gas assisted etch.

As known in the art, selective deposition of a semiconductor material can be performed only at a temperature at which etching of the semiconductor material can be effectively performed. Hydrogen chloride is a commonly employed etchant for selective deposition processes for semiconductor materials such as silicon or a silicon-containing alloy. Hydrogen chloride as an etchant is effective only at temperatures above than 625° C. At temperatures lower than 625° C., conventional selective deposition processes for a semiconductors fail because hydrogen chloride provides only negligible etch rates, thereby rendering selectivity unattainable during epitaxial growth.

### SUMMARY

A selective semiconductor deposition process that employs an alternating sequence of a deposition step and an etch step. During each deposition step, a semiconductor material is deposited on single crystalline surfaces at a greater deposition rate than on insulator surfaces. A combination of hydrogen chloride and a germanium-containing gas is employed within each etch step. The germanium-containing gas is employed to enhance the etch rate of hydrogen chloride, thereby enabling an effective etch process at temperatures as low as 380° C. Deposited semiconductor material is removed from above insulator surfaces, while a fraction of the deposited semiconductor material remains on semiconductor surfaces after each etch step, thereby providing a selective deposition of the semiconductor material.

According to an aspect of the present disclosure, a method is provided for depositing a semiconductor material by performing a sequence of processing steps at least once. The sequence of processing steps includes a deposition step that deposits a semiconductor material on a substrate by flowing at least one precursor gas into a process chamber including the substrate. The sequence of processing steps further includes an etch step that etches at least a portion of the deposited semiconductor material by flowing a combination of a hydrogen chloride gas and a germanium-containing gas into the process chamber.

### BRIEF DESCRIPTION OF THE DRAWINGS

FIG. 1 is a schematic diagram illustrating an exemplary apparatus configured for selective deposition process for a semiconductor employing cyclic deposit and etch (CDE) during a deposition step according to an embodiment of the present disclosure.

FIG. 2 is a schematic diagram illustrating an exemplary apparatus configured for the selective deposition process for a semiconductor employing cyclic deposit and etch (CDE) during an etch step according to an embodiment of the present disclosure.

FIG. 3 shows the XRD data from an epitaxial semiconductor film having a boron doping and a germanium concentration of 19 atomic percent and deposited employing the methods of the present disclosure.

### DETAILED DESCRIPTION

As stated above, the present disclosure relates to a method for low temperature selective deposition employing a germanium-containing gas assisted etch. Aspects of the present disclosure are now described in detail with accompanying figures. It is noted that like reference numerals refer to like elements across different embodiments. The drawings are not necessarily drawn to scale.

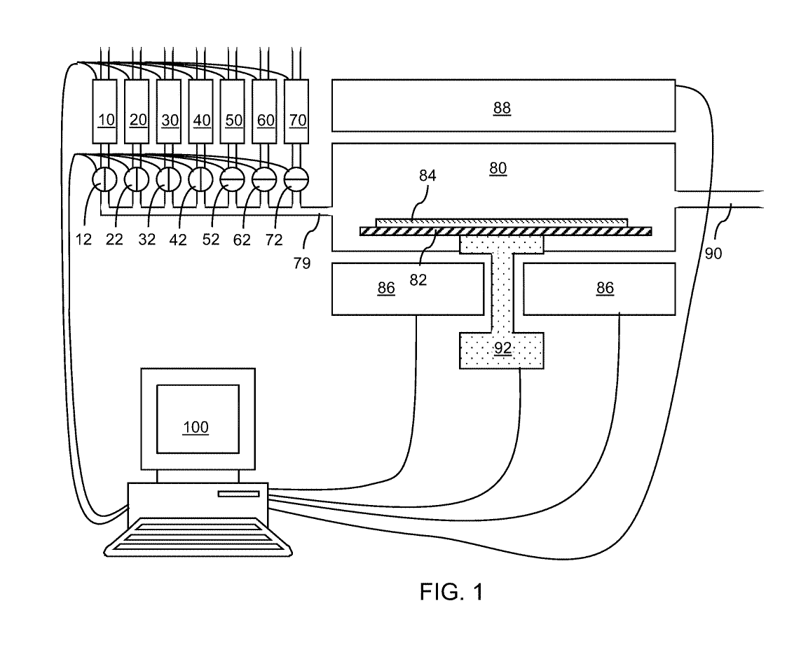

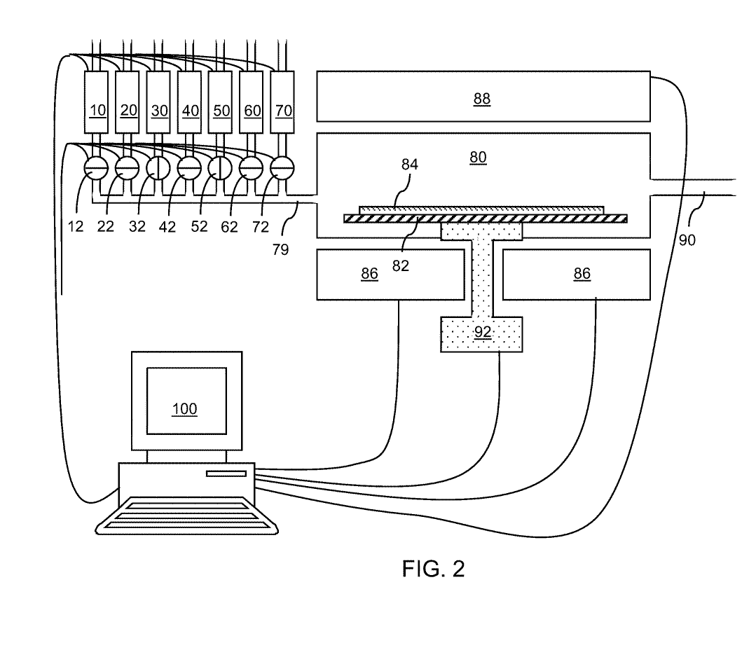

Referring to FIGS. 1 and 2, an exemplary apparatus configured for selective deposition of a semiconductor material employing cyclic deposit and etch (CDE) is illustrated. FIG. 1 shows the exemplary apparatus during a deposition step, and FIG. 2 shows the exemplary apparatus during an etch step. The CDE selective semiconductor deposition process can employ deposition steps and etch steps alternately to provide selectivity of growth of a single crystalline epitaxial semiconductor on single crystalline surfaces of a semiconductor substrate, while preventing cumulative deposition of an amorphous or polycrystalline semiconductor on dielectric surfaces such as surfaces of a silicon oxide surfaces and silicon nitride surfaces of a patterned semiconductor substrate. As used herein, a “selective deposition” process refers to a deposition process that deposits a material only on some surfaces while preventing deposition of the material on other surfaces.

The exemplary apparatus is configured to provide process gases, etch gases, and purge gases to a process chamber 80, which can be configured as a reduced pressure process chamber configured to operate in a pressure range from 1 Torr and 300 Torr during deposition steps and etch steps. An inlet gas manifold 79 is provided on one side of the process chamber 80, and an exhaust manifold 90 is provided on the other side of the process chamber 80. The exhaust manifold 90 is connected to a vacuum pump (not shown) and a scrubber (not shown). Alternatively, the process chamber 80 can be configured to operate at, or close to, atmospheric pressure (760 Torr).

A susceptor 82 is located in the process chamber 80. The susceptor 82 is configured to hold a wafer 84, which can be, for example, a semiconductor substrate such as a blanket silicon substrate or a patterned substrate including single crystalline silicon portions. In one embodiment, the susceptor 82 can have a thermal mass greater than the thermal mass of the wafer 84 to facilitate heating of the wafer 84 once the wafer is placed on the susceptor. In one embodiment, the susceptor 84 can be configured to rotate while holding the wafer 84, thereby providing a rotation to the wafer 84 to enhance the uniformity of the semiconductor film deposited on the wafer 84.

The process chamber 80 can have a transparent enclosure to let in radiation from external heating elements. A lower temperature control unit 86 and an upper temperature control unit 88 can be provided below, and above, the process chamber 80, respectively. Each of the lower temperature control unit 86 and the upper temperature control unit 88 can include heating elements, a pyrometer, and a temperature control feedback circuitry designed to control the power supplied to the heating elements in order to stabilize the temperature of the susceptor 82 and the wafer 84 at a target temperature.

The exemplary apparatus can be configured to provide a carrier gas to the process chamber 80 through a first mass flow controller (MFC) 10 and a first valve 12. The first valve 12 is normally closed, and is opened when the carrier gas flows into the process chamber 80. The first MFC 10 controls the flow rate of the carrier gas into the process chamber 80. In one embodiment, the first MFC 10 can be configured to provide a flow rate in a range from 1 standard liter per minute (slm) to 1,000 slm. The carrier gas can be, for example, hydrogen gas, helium gas, nitrogen gas, argon gas, or a combination thereof.

The exemplary apparatus can be configured to provide at least one precursor gas for depositing a semiconductor material to the process chamber through at least one MFC. One or more precursor gases can be provided. In an illustrative example, the at least one precursor gas can include a first precursor gas that can be provided into the process chamber 80 through a second MFC 20, and a second precursor gas that can be provided into the process chamber 80 through a third MFC 30. While the present disclosure is described for processes and apparatus employing two precursor gases, embodiments employing a single precursor gas for deposition of a semiconductor material or three or more precursor gases for deposition of a semiconductor material are also contemplated herein.

In one embodiment, the at least one precursor gas can include a silicon-containing precursor gas. As used herein, a silicon-containing precursor gas refers to a precursor gas that includes silicon. Silicon-containing precursor gases include SiₙH₂ₙ₊₂ compounds in which n is a positive integer.

In one embodiment, the silicon-containing precursor gas can include a high order silane gas that is provided into the process chamber 80 through a second MFC 20 and a second value 22 from a high order silane source. As used herein, a “high order silane” refers to SiₙH₂ₙ₊₂ compounds in which n is greater than 3. For example, high order silanes that can be employed for the purposes of the present disclosure include Si₄H₁₀, Si₅H₁₂, Si₆H₁₄, Si₇H₁₆, Si₈H₁₈, Si₉H₂₀, etc. The high order silane gas source can be a bubbler that is configured to provide a vapor of the high order silane in a carrier gas, which can be, for example, hydrogen gas, helium gas, nitrogen gas, argon gas, or a combination thereof. The vapor pressure of the high order silane gas can be controlled within a target range by controlling the temperature of the bubbler. The second shut-off valve 22 is normally closed, and is opened when the high order silane gas flows into the process chamber 80. In one embodiment, the second MFC 20 can be configured to provide a flow rate in a range from 10 standard cubic centimeters per minute (sccm) to 10 slm.

In one embodiment, the at least one precursor gas can include a germanium-containing precursor gas. As used herein, a germanium-containing precursor gas refers to a precursor gas that includes germanium. The germanium-containing precursor gas can be provided into the process chamber 80 through a third MFC 30 and a third value 32 from a germanium precursor gas source. The germanium precursor gas can be germane (GeH₄) or digermane (Ge₂H₆) or germanium tetrachloride (GeCl₄). The germanium-containing precursor gas can be provided from a compressed gas tank. The third shut-off valve 32 is normally closed, and is opened when the germanium-containing precursor gas flows into the process chamber 80. In one embodiment, the third MFC 30 can be configured to provide a flow rate in a range from 10 sccm to 10 slm.

In one embodiment, the at least one precursor gas can include a carbon-containing precursor gas. As used herein, a carbon-containing precursor gas refers to a precursor gas that includes carbon. The carbon-containing precursor gas can be provided in lieu of the germanium-containing precursor gas. In this case, the carbon-containing precursor gas can be provided into the process chamber 80 through a third MFC 30 and a third value 32 from a carbon-containing precursor gas source. Alternately, the carbon-containing precursor gas can be provided in addition to the germanium-containing precursor gas. In this case, the carbon-containing precursor gas can be provided into the process chamber through another MFC (not shown) and another valve from a carbon-containing precursor gas. The carbon-containing precursor gas can be a saturated carbon hydride having a formula of CᵢH₂ᵢ₊₂, or unsaturated carbon hydrides having a formula of CⱼH2ⱼ or Cₖ₊₁H₂ₖ, in which i, j, and k are positive integers. Alternatively, the carbon-containing precursor gas can be a molecule including silicon, carbon, and hydrogen such as SiₚH₃C_{q}H_{2q+1} or SiᵣH₃CₜH₂ₜ₋₁. In one embodiment, the carbon-containing precursor gas can be monomethylsilane (MMS). The carbon-containing precursor gas can be provided from a compressed gas tank. In this case, a shut-off valve in the path of the supply line for the carbon-containing precursor gas is normally closed, and is opened when the carbon-containing precursor gas flows into the process chamber 80. In one embodiment, the MFC in the path of the supply line for the carbon-containing precursor gas can be configured to provide a flow rate in a range from 10 sccm to 10 slm.

In one embodiment, the at least one precursor gas can include precursor gases for a compound semiconductor material. The compound semiconductor material can be a III-V compound semiconductor material, a II-VI compound semiconductor material, or an organic semiconductor material. Any precursor gas known in the art for depositing a compound semiconductor material can be employed as the at least one precursor gas. The at least one precursor gas for depositing a compound semiconductor material can be supplied through the second MFC 20 and the second valve 22, through the third MFC 30 and the third valve 32, and/or at least another MFC (not shown) and at least another valve (not shown) that are configured to flow the at least one precursor gas for the compound semiconductor material into the process chamber 80.

A dopant gas can be provided into the process chamber 80 through a fourth MFC 40 and a fourth value 42 from a dopant gas source, which can be a compressed gas tank. The dopant gas can be diborane (B₂H₆), phosphine (PH₃), arsine (AsH₃), or stibine (SbH₃). In one embodiment, the dopant gas can be diborane. The fourth shut-off valve 42 is normally closed, and is opened when the dopant gas flows into the process chamber 80. In one embodiment, the fourth MFC 40 can be configured to provide a flow rate in a range from 1 sccm to 1 slm. A plurality of dopant gases can be provided employing multiple MFC's and multiple valves configured to provide each of the plurality of dopant gases into the process chamber.

The combination of the carrier gas, the at least one precursor gas, and the dopant gas allows deposition of silicon, a silicon-germanium alloy, a silicon-carbon alloy, a silicon-germanium-carbon alloy, a compound semiconductor material, or combinations thereof with, or without, in-situ doping with electrical dopants (i.e., p-type dopants or n-type dopants) on the wafer 84 within the process chamber. In one embodiment, the semiconductor material deposited on the wafer 84 can be a silicon-germanium alloy with, or without, in-situ doping with electrical dopants (i.e., p-type dopants or n-type dopants). In one embodiment, the semiconductor material deposited on the wafer 84 can be a semiconductor material different from a silicon-germanium alloy, which can be silicon, a silicon-carbon alloy, a silicon-germanium-carbon alloy, a compound semiconductor material, or combinations thereof with, or without, in-situ doping with electrical dopants. In one embodiment, the semiconductor material deposited on the wafer 84 can be a semiconductor material that does not include germanium, which can be silicon, a silicon-carbon alloy, a compound semiconductor material, or combinations thereof with, or without, in-situ doping with electrical dopants.

Hydrogen chloride (HCl) gas can be provided into the process chamber 80 through a fifth MFC 50 and a fifth value 52 from a hydrogen chloride source, which can be a compressed tank including hydrogen chloride. The fifth shut-off valve 52 is normally closed, and is opened when the germanium-containing gas flows into the process chamber 80. In one embodiment, the fifth MFC 50 can be configured to provide a flow rate in a range from 100 sccm to 100 slm.

A purge gas can be provided into the process chamber 80 through a sixth MFC 60 and a sixth value 62 from a purge gas source, which can be a compressed tank including the purge gas. The purge gas can be nitrogen or hydrogen. The sixth shut-off valve 62 is normally open, and is closed when the purge gas does not flow into the process chamber 80. In one embodiment, the sixth MFC 60 can be configured to provide a flow rate in a range from 100 sccm to 100 slm.

Optionally, a germanium-containing gas that is different from the germanium-containing precursor can be provided into the process chamber 80 through a seventh MFC 70 and a seventh value 72 from a germanium-containing gas source. The germanium-containing gas can be, for example, germanium tetrachloride (GeCl₄) or germanium tetrafluoride (GeF₄). Alternately, if the germanium source gas one of germane (GeH₄) and digermane (Ge₂H₆), the germanium-containing gas can be the other of germane and digermane. The germanium-containing gas can be provided from a compressed gas tank, or can be provided by any other alternate means for providing the germanium-containing gas as known in the art. The seventh shut-off valve 72 is normally closed, and is opened when the germanium-containing gas flows into the process chamber 80. In one embodiment, the seventh MFC 70 can be configured to provide a flow rate in a range from 10 sccm to 10 slm.

The wafer 84 can be a patterned semiconductor substrate including at least one physically exposed semiconductor surface and at least one physically exposed dielectric surface. In one embodiment, the wafer 84 can include at least one physically exposed silicon surface and at least one physically exposed dielectric surface. The CDE semiconductor selective deposition can be performed by alternately performing a deposition step and an etch step.

A susceptor motion control assembly 92 can be provided to move the susceptor 82 during the deposition step and etch steps. The susceptor motion control assembly 92 can be configured to rotate the susceptor around the center axis of the susceptor 82, thereby rotating the wafer 82 during the deposition steps and the etch steps. In one embodiment, the susceptor motion control assembly 92 can include a motor located outside a vacuum enclosure of the process chamber 80, a magnetic coupling device, and a rotation axis structure connected to the susceptor 82 and attached to inner components of the magnetic coupling device. The susceptor motion control assembly 92 can rotate the wafer 84, for example, at a rate from 0.2 revolution per minute (rpm) to 60 rpm.

The exemplary apparatus can further include a process control device 100, which can be a computer, a set of interconnected computers, a dedicated standalone computing device, a portable computing device, or any other type of device capable of controlling the pressure and temperature of the process chamber 80 and the gas flow into the process chamber 80 by activating each of the valves (12, 22, 32, 42, 52, 62, 72) and the MFC's (10, 20, 30, 40, 50, 60, 70). Further, the process control device 100 can be configured to run a process control program, or a “process recipe,” that specifies target process parameters for performing each of the deposition steps and each of the etch steps. For example, the process control program can include specifications for target temperatures, target pressures, and target gas flow rates for each of the gases controlled by the valves (12, 22, 32, 42, 52, 62, 72) and the MFC's (10, 20, 30, 40, 50, 60, 70) at each stage of the deposition steps and at each stage of the etch steps. In one embodiment, the process control device can be configured to perform the plurality of deposition steps and the plurality of etch steps as a series of alternately performed deposition steps and etch steps.

Referring to FIG. 1, during each deposition step, an undoped or doped semiconductor material is formed on the wafer. At least one suitable precursor gas for depositing the undoped or doped semiconductor material is flowed into the process chamber 80 through corresponding at least one MFC (20, 30) and at least one corresponding shut-off valve (22, 32) optionally in conjunction with the carrier gas and/or the dopant gas. For example, if the at least one precursor gas is configured to flow through the second MFC 20 and/or the third MFC 30, the second shut-off value 22 and/or the third shut-off value 32 are opened, and the second MFC 20 and/or the third MFC 30 are controlled to allow simultaneous flow of the at least one precursor gas into the process chamber 80. Optionally, the first shut-off value 12 can be opened and the first MFC 10 can be controlled to allow the carrier gas to flow into the process chamber with the at least one precursor gas. The temperature of the wafer 84 during the deposition step can be in a range from, and including, 380° C. to, and including, 600° C.

In one embodiment, if the combination of a high order silane gas and a germanium precursor gas is employed, a high quality silicon-germanium alloy can be deposited at a high growth rate at low temperatures. The high order silane is employed as the silicon precursor, and germane or digermane can be employed as the germanium precursor.

The high order silane gas and the germanium precursor gas can be delivered into the process chamber 80 with or without the carrier gas. The partial pressure of the high order silane gas during the deposition step can be from 0.1 mTorr to 10 Torr. The partial pressure of the germanium precursor gas during the deposition step can be from 0.1 mTorr to 10 Torr. The ratio of the partial pressure of the high order silane gas to the partial pressure of the germanium precursor gas can be from 0.001 to 1,000, although lesser and greater ratios can also be employed. The atomic percentage of germanium atoms relative to the total semiconductor atoms (i.e., the silicon atoms and the germanium atoms) in the deposited undoped or doped silicon alloy can be from nearly 0% to nearly 100%. Thus, the atomic percentage of germanium within the doped or undoped semiconductor can be varied from 0% to 100% by adjusting the ratio of the flow rates of the high order silane gas and the germanium precursor gas, and by adjusting the deposition temperature and pressure during the deposition step.

The temperature of the wafer 84 during the deposition step can be in a range from, and including, 380° C. to, and including, 550° C. The use of the high order silane gas provides a significant increase in the deposition rate in the temperature range from, and including, 380° C. to, and including, 550° C. relative to a deposition process employing monosilane (SiH₄) or disilane (Si₂H₆). In one embodiment, the temperature of the wafer 84 during the deposition step can be in a range from, and including, 380° C. to, and including, 400° C. In yet another embodiment, the temperature of the wafer 84 during the deposition step can be not less than 380° C. and less than 400° C. The total pressure of the process chamber 80 during the deposition step can be from 3 Torr to 300 Torr, although lesser and greater pressures can also be employed.

While germane or digermane can be employed to provide a high deposition rate for a semiconductor, digermane can provide a higher deposition rate at the same temperature. In one embodiment, the deposition rate for single crystalline semiconductor can be from 1 nm/min to 30 nm/min, although lesser and greater deposition rates can also be used. In another embodiment, the deposition rate for single crystalline semiconductor can be from 5 nm/min to 30 nm/min. In yet another embodiment, the deposition rate for single crystalline semiconductor can be from 10 nm/min to 30 nm/min.

Portions of the undoped or doped semiconductor deposited on single crystalline semiconductor surfaces (such as single crystalline silicon surfaces) are epitaxially aligned to the underlying single crystalline semiconductor material, and become epitaxial semiconductor portions. Portions of the undoped or doped semiconductor deposited on dielectric surfaces (such as surfaces of silicon oxide or silicon nitride) and amorphous or polycrystalline semiconductor surfaces are formed as amorphous or polycrystalline becomes amorphous or polycrystalline semiconductor portions.

The semiconductor portions can be formed as undoped semiconductor portions or doped semiconductor portions having a p-type doping or an n-type doping. In one embodiment, the semiconductor portions can be formed as undoped semiconductor portions. In this case, the fourth shut-off value 42 is shut, and the fourth MFC 40 can be controlled not to allow any flow of the dopant gas.

In another embodiment, the semiconductor portions can be formed as doped semiconductor portions having a p-type doping or n-type doping. Deposition of boron-doped semiconductor can be performed by in-situ doping of the semiconductor. For example, the semiconductor portions can be formed as boron-doped (i.e., B-doped) semiconductor portions. In this case, a dopant gas including boron such as diborane can be flowed into a reaction chamber concurrently with the silicon precursor and the germanium precursor. The fourth shut-off valve 42 is opened, and the fourth MFC can be controlled to flow the dopant gas into the process chamber 80.

In one embodiment, the dopant gas can be diborane, and the deposited semiconductor can be doped with boron at a boron concentration from 1.0×10¹⁷/cm³ to 3.0×10²¹/cm³, although lesser and greater boron concentrations can also be employed. In another embodiment, the deposited semiconductor can be doped with boron at a boron concentration from 1.0×10¹⁹/cm³ to 2.0×10²¹/cm³. In yet another embodiment, the deposited semiconductor can be doped with boron at a boron concentration from 1.0×10²⁰/cm³ to 1.0×10²¹/cm³.

Referring to FIG. 2, during each etch step, the undoped or doped semiconductor portions are etched from the wafer 84. The etch rate of the undoped or doped semiconductor is dependent on the crystalline structure. Specifically, single crystalline undoped or doped semiconductor is etched at a lower etch rate than amorphous or polycrystalline semiconductor. Thus, all amorphous or polycrystalline semiconductor deposited in the previous deposition cycle can be removed in the etch step, while a fraction of each epitaxial semiconductor portion deposited during the previous deposition step remains on the wafer 82 at the end of each etch step.

The fifth shut-off value 52 and at least one of the third shut-off value 32 and the optional seventh shut-off valve 72 are opened, and the fifth MFC 50 and at least one of the third MFC 30 and the optional seventh MFC 70 are controlled to allow simultaneous flow of the hydrogen chloride gas and a germanium-containing gas into the process chamber 80. The germanium-containing gas that is flowed into the process chamber includes at least one of the germanium precursor gas that flows through the third MFC 30 and the germanium-containing gas that is different from the germanium precursor gas and flows through the optional seventh MFC 70. Thus, the germanium-containing can include at least of germane (GeH₄), digermane (Ge₂H₆), germanium tetrachloride (GeCl₄), and germanium tetrafluoride (GeF₄).

While the etch rate of hydrogen chloride at temperatures lower than 625° C. is negligible, the etch rate of the combination of hydrogen chloride and the germanium-containing gas that is simultaneously flowed into the process chamber 80 is significantly enhanced over the etch rate of hydrogen chloride at temperatures lower than 625° C. Without wishing to be bound by any theory, it is conjectured that the mechanism for significantly enhancing the etch rate and the germanium concentration may be the interaction of hydrogen chloride with the germanium-containing gas. Thus, addition of the germanium-containing gas enhances the etch rate during the etch step so as to provide a significant etch rate for semiconductors in the temperature range from 380° C. to 630° C. The germanium-containing gas can be, for example, germane (GeH₄), digermane (Ge₂H₆), germanium tetrachloride (GeCl₄), germanium tetrafluoride (GeF₄), or combinations thereof.

In one embodiment, the germanium-containing gas is the germanium precursor gas, and is provided through the third MFC 30 and the third valve 32. In this case, the germanium-containing gas employed during the etch step can be germane or digermane.

In another embodiment, the germanium-containing gas is the germanium-containing gas that is different from the germanium precursor gas, and is provided through the seventh MFC 70 and the seventh valve 72. In one case, the germanium precursor gas can be germane, and the germanium-containing gas flowed during the etch process can be digermane, germanium tetrachloride (GeCl₄), germanium tetrafluoride, or combinations thereof. In another case, the germanium precursor gas can be digermane, and the germanium-containing gas flowed during the etch process can be germane, germanium tetrachloride (GeCl₄), germanium tetrafluoride, or combinations thereof. In yet another case, the germanium precursor gas can be germanium tetrachloride, and the germanium-containing gas flowed during the etch process can be germane, digermane, germanium tetrafluoride, or combinations thereof.

In yet another embodiment, the germanium-containing gas can be a combination of the germanium precursor gas that is flowed through the third MFC 30 and the third valve 32 and another germanium-containing gas that is different from the germanium precursor gas, which is provided through the seventh MFC 70 and the seventh valve 72.

The partial pressure of the hydrogen chloride gas during the etch step can be from 1 Torr to 300 Torr. The partial pressure of the germanium-containing gas during the etch step can be from 0.1 mTorr to 10 Torr. The ratio of the partial pressure of the hydrogen chloride gas to the partial pressure of the germanium-containing gas can be from 10 to 100,000, although lesser and greater ratios can also be employed. The total pressure of the process chamber 80 during the etch step can be from about 1 Torr to 300 Torr, although lesser and greater pressures can also be employed.

The temperature of the wafer 84 during the etch step can be in a range from, and including, 380° C. to, and including, 630° C. In one embodiment, the temperature of the wafer 84 during the etch step can be in a range from, and including, 430° C. to, and including, 560° C. In yet another embodiment, the temperature of the wafer 84 during the etch step can be in a range from, and including, 460° C. to, and including, 540° C. In yet another embodiment, the temperature of the wafer 84 during the etch step can be in a range from, and including, 380° C. to, and including, 430° C. In yet another embodiment, the temperature of the wafer 84 during the etch step can be not less than 380° C. and less than 430° C.

In one embodiment, the temperature of the wafer 84 during the etch step can be the same as the temperature of the wafer 84 during the deposition step. In another embodiment, the temperature of the wafer 84 can be elevated during each etch step above the temperature of the deposition step, for example, by a temperature differential greater than 0° C. and less than 50° C.

A selectivity ratio is defined as the etch rate for an amorphous or polycrystalline film divided by the etch rate of an epitaxial film having a same composition as the amorphous or polycrystalline film. The use of a germanium-containing gas during the etch step provides a selectivity ratio greater than 1.0 at processing temperatures less than 580° C. In one embodiment, the use of a germanium-containing gas during the etch step provides a selectivity ratio greater than 1.0 for doped or undoped semiconductors deposited and etched at a temperature at, or lower than, 550° C.

In one embodiment, selectivity ratios greater than 2.0 can be provided during the etch step. In another embodiment, selectivity ratios greater than 4.0 can be provided during the etch step. In yet another embodiment, selectivity ratios greater than 7.0 can be provided during the etch step.

The etch rate for single crystalline semiconductors of the etch process can be from 1 nm/min to 100 nm/min, although lesser and greater etch rates can also be employed. In one embodiment, the etch rate for single crystalline semiconductors of the etch process can be from 1 nm/min to 80 nm/min, although lesser and greater etch rates can also be employed. In another embodiment, the etch rate for single crystalline semiconductors of the etch process can be from 2 nm/min to 10 nm/min.

The deposited doped or undoped semiconductors deposited on dielectric surfaces tend to become less amorphous and more polycrystalline with increasing deposition temperature. For a given germanium concentration in a semiconductor, the lower the deposition temperature, the greater the selectivity ratio and the greater the critical thickness beyond which a film of the semiconductor relaxes.

In one embodiment, an epitaxial semiconductor having a germanium concentration in a range from 0.01% to 60% in atomic concentration can be selectivity deposited in a temperature range from 380° C. to 550° C.

In one embodiment, a relatively small amount of hydrogen chloride can be flowed into the process chamber 80 during each deposition step. The presence of hydrogen chloride during the deposition step improves the quality of epitaxial semiconductor in terms of single crystallinity of the deposited semiconductor (i.e., the degree of alignment in the epitaxial semiconductor). This effect was experimentally confirmed by comparing X-ray diffraction spectra of a first epitaxial semiconductor deposited employing a deposition step in which hydrogen chloride was flowed with tetrasilane (Si₄H₁₀) and germane and a second epitaxial semiconductor deposited employing a deposition step in which hydrogen chloride was not flowed while tetrasilane and germane were flowed. Fringe peaks were present in the XRD spectra of the first epitaxial semiconductor, while fringe peaks were not present in the XRD spectra of the second epitaxial semiconductor.

In one embodiment, the flow rate of hydrogen chloride during each deposition step can be from 0.1% to 100% of the combined flow rate of the high order silane gas and the germanium precursor gas, although lesser and greater percentages can also be employed. In another embodiment, the flow rate of hydrogen chloride during each deposition step can be from 0.5% to 10% of the combined flow rate of the high order silane gas and the germanium precursor gas.

In embodiments in which germanium tetrachloride is employed as the germanium precursor gas, a uniform germanium concentration profile without any germanium pile-up was observed in doped or undoped epitaxial semiconductors. It is conjectured that strong Si—CI bonds prevents intermixing of germanium and silicon in this case.

In one embodiment, the methods of the present disclosure can be employed to embed epitaxial semiconductors in a source and/or a drain region of a field effect transistor including a silicon channel to provide a compressive stress along the lengthwise direction of the channel, i.e., along the direction connecting the source region and the drain region of the field effect transistor. As used herein, a “field effect transistor” refers to any transistor that employs field effect to control the operation of the device, and includes metal-semiconductor-insulator (MOS) field effect transistors, junction field effect transistors, and all types of planar and fin-configuration variants thereof as known in the art.

The etch process of the present disclosure can be employed in conjunction with any semiconductor material deposition process that deposits a semiconductor material that can be etched with hydrogen chloride. The presence of the germanium-containing gas accelerates the etch rate of hydrogen chloride at low temperatures, and an effective etch process for a selective deposition of a semiconductor material can be provided at temperatures as low as 380° C., and potentially at even lower temperatures.

### EXAMPLES

A study was performed employing a reduced pressure chemical vapor deposition (RPCVD) chamber configured to deposit a semiconductor on a 300 mm diameter substrate. The system that included the RPCVD chamber was a horizontal, single-wafer, multi-chamber system, including two load-lock chambers, a transfer chamber, and two process modules each including a process chamber. One of the two process chambers was the PPCVD chamber. The load-lock chambers were located before the transfer chamber to maintain a clean inert environment for transferring wafers in and out of the system. Each load-lock chamber was configured to hold up to 25 wafers.

In the process module including the RPCVD chamber (which is herein referred to as the “RPCVD module”), upper and lower lamp modules were used to radiantly heat the wafer and a susceptor through upper and lower quartz domes, which are parts of an enclosure in which the wafer is loaded for selective deposition. The temperature of the wafer was controlled by optical pyrometers and a closed loop proportional, integral, and derivative (PID) control system. The RPCVD chamber was configured to rotate the wafer and the susceptor during the selective deposition process during the selective deposition process. Process gases were flowed across, and over, the front surface of the wafer upon entering the process chamber at one side of the chamber, and exited the process chamber through an exhaust manifold located at the other side of the chamber.

The process module was equipped with liquid precursor delivery systems to provide vapors derived from liquid precursors into the RPCVD chamber through mass flow controllers (MFC's). Semiconductor films were deposited on both blanket silicon (001) substrates and patterned silicon (001) substrates. The blanket and patterned silicon (001) substrate had a light p-type doping corresponding to a resistivity of 7˜10 Ω-cm. The deposition temperatures were set at 380° C. and 400° C., and the pressure during the deposition process was 10 Torr.

Liquid vapor high order silanes (SiₙH₂ₙ₊₂; n>3) were selected as the silicon source gas to achieve high growth rate at low temperature. The precursor vapor was delivered from a bubbler to the RPCVD chamber employing a hydrogen carrier gas. Germane (GeH₄) diluted at 10% in hydrogen gas was used as the Ge source gas. Boron dopant was introduced into the RPCVD chamber by flowing 1% diborane (B₂H₆) in hydrogen gas to the RPCVD chamber. An etch chemistry employing hydrogen chloride (HCl) and germane (GeH₄) was employed at 380° C. or 400° C., which was selected to be the same temperature as the deposition temperature for the boron-doped semiconductor.

In a first series of runs, tetrasilane (Si₄H₁₀) gas was delivered as a silicon-containing precursor gas at a flow rate of 29 mg/min, germane (GeH₄) gas was delivered as a germanium-containing precursor gas at a flow rate of 280 sccm, 10% diborane in hydrogen was delivered as a dopant gas at a flow rate of 100 sccm, resulting in deposition of an epitaxial silicon-germanium alloy at a growth rate of 9.0 nm/min at 380° C. and at a growth rate of 9.5 nm/min at 400° C., respectively. Secondary ion mass spectroscopy measurement on deposited boron-doped epitaxial silicon-germanium alloy film shows that the atomic concentration of germanium was 7.0% and 8.35% for the deposition temperatures of 380° C. and 400° C., respectively.

In a second series of runs, tetrasilane (Si₄H₁₀) gas was delivered as a silicon-containing precursor gas at a flow rate of 29 mg/min, germane (GeH₄) gas was delivered as a germanium-containing precursor gas at a flow rate of 800 sccm, 10% diborane in hydrogen was delivered as a dopant gas at a flow rate of 100 sccm, resulting in deposition of an epitaxial silicon-germanium alloy at a growth rate of 9.1 nm/min at 380° C. and at a growth rate of 10.9 nm/min at 400° C., respectively. Secondary ion mass spectroscopy measurement on deposited boron-doped epitaxial silicon-germanium alloy film shows that the atomic concentration of germanium was 19% and 21% for the deposition temperatures of 380° C. and 400° C., respectively.

Due to the non-selective nature of deposition from high-order silanes as defined above, selective deposition on patterned wafers was achieved using an isothermal cyclic deposit and etch (CDE) process at 380° C. or 400° C. This isothermal process avoided cycling to higher temperature from deposition for the etch steps, and thus, was advantageous for providing high throughput and maintaining the strain in the deposited film by minimizing exposure to an elevated temperature during the etch steps.

During each etch step, 350 sccm of HCl gas was delivered into the process chamber. In addition, germane (GeH₄) gas was delivered as a germanium-containing gas at a flow rate of 300 sccm. The measured etch rate depended on the temperature and the germanium concentration of the boron-doped epitaxial silicon-germanium alloy films. At 380° C., the etch rates were 2.1 nm/min for the boron-doped epitaxial silicon-germanium alloy film with 7.0% germanium in atomic concentration, and 2.0 nm/min for the boron-doped epitaxial silicon-germanium alloy film with 19% germanium in atomic concentration. At 400° C., the etch rates were 1.0 nm/min for the boron-doped epitaxial silicon-germanium alloy film with 8.35% germanium in atomic concentration, and 1.7 nm/min for the boron-doped epitaxial silicon-germanium alloy film with 21% germanium in atomic concentration.

The thickness and the substitutional Ge concentration in the epitaxial boron-doped semiconductor films were determined by high-resolution X-ray diffraction (XRD) data along the (004) direction. Secondary ion mass spectrometry (SIMS) measurements were performed to determine the total boron concentration and the total germanium concentration in the epitaxial boron-doped semiconductor films. A 500 eV O₂⁺ beam was used to collect boron and germanium depth profiling information. Boron concentration was quantified with boron implant standards in silicon, and was subsequently corrected for the yield difference due to the germanium concentration. Germanium was quantified with a set of semiconductor samples and implant standards. Within error limits, the germanium concentration measured from SIMS matched the germanium concentration calculated by XRD. The measured germanium concentrations indicated a fully-strained semiconductor layer. Taping mode atomic force microscopy (AFM) was employed to study the surface roughness of the epitaxial boron-doped semiconductor films. The film quality and morphology were investigated by cross-sectional TEM.

In the first series of runs, in-situ boron doped silicon-germanium material portions were selectively deposited on silicon surfaces by performing a sequence of processing steps multiple times. The sequence included a deposition step, a first purge step in which only hydrogen was flown into a processing chamber, an etch step, and a second purge step in which only hydrogen was flown into the processing chamber. The duration of each purge step was 1 minute. The number of repetition for the sequence was 8 or 20. A net deposition thickness for the in-situ boron doped silicon-germanium epitaxial film per each sequence of processing steps was about 1.1 nm per sequence at 380° C., and in a range from 2.6 nm per sequence to 3.3 nm per sequence at 380° C.

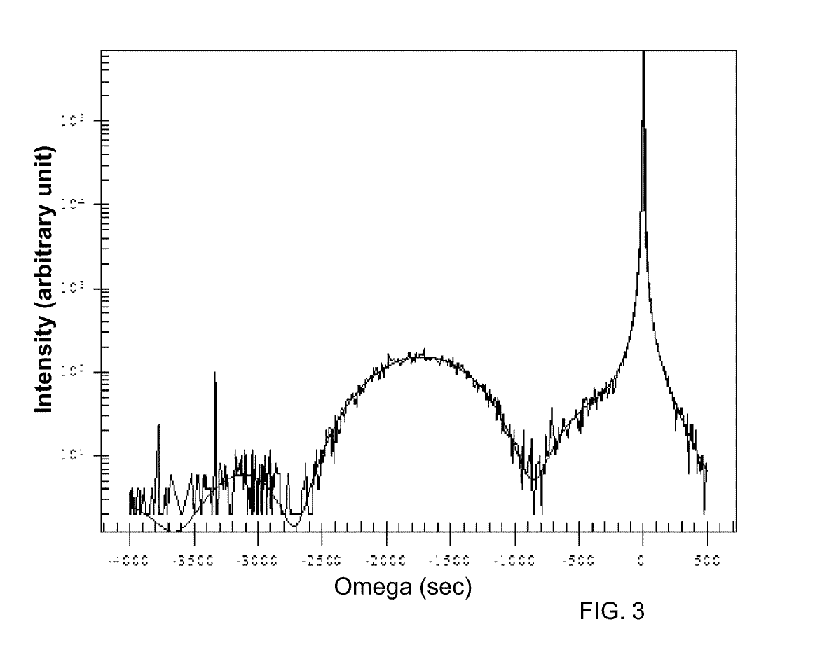

The quality of the in-situ boron doped silicon-germanium epitaxial material was verified by X-ray diffraction (XRD). FIG. 3 shows the XRD data from an in-situ boron doped epitaxial silicon germanium alloy film grown at 380° C. and having a germanium concentration of 19 atomic percent and deposited employing the methods of the present disclosure. The measured XRD data gives an excellent fit to a theoretical curve (the smooth curve) for a single crystalline silicon-germanium alloy having a germanium concentration of 19 atomic percent.

While the present disclosure has been particularly shown and described with respect to preferred embodiments thereof, it will be understood by those skilled in the art that the foregoing and other changes in forms and details may be made without departing from the spirit and scope of the present disclosure. Each of the various embodiments of the present disclosure can be implemented alone, or in combination with any other embodiments of the present disclosure unless expressly disclosed otherwise or otherwise impossible as would be known to one of ordinary skill in the art. It is therefore intended that the present disclosure not be limited to the exact forms and details described and illustrated, but fall within the scope of the appended claims.

What is claimed is:

1. A method of depositing a semiconductor material by performing a sequence of processing steps at least once, said sequence of processing steps comprising:
a deposition step that deposits a semiconductor material on a substrate by flowing at least one precursor gas into a process chamber including said substrate; and
an etch step that etches at least a portion of said deposited semiconductor material by flowing a combination of a hydrogen chloride gas and a germanium-containing gas into said process chamber.

2. The method of claim 1, wherein each of said at least one deposition step is performed at a deposition temperature in a range from, and including, 380° C. to, and including, 600° C.

3. The method of claim 2, wherein each of said at least one etch step is performed at an etch temperature in a range from, and including, 380° C. to, and including, 630° C.

4. The method of claim 3, wherein said etch temperature is the same as said deposition temperature.

5. The method of claim 3, wherein said etch temperature is higher than said deposition temperature.

6. The method of claim 5, wherein said etch temperature is higher than said deposition temperature by no more than 50° C.

7. The method of claim 1, wherein each of said at least one deposition step is performed at a deposition temperature in a range from, and including, 380° C. to, and including, 400° C.

8. The method of claim 7, wherein each of said at least one etch step is performed at an etch temperature in a range from, and including, 380° C. to, and including, 430° C.

9. The method of claim 1, wherein said germanium-containing gas is a germanium hydride.

10. The method of claim 1, wherein said germanium-containing gas is germanium chloride.

11. The method of claim 1, wherein said germanium-containing gas is germanium fluoride.

12. The method of claim 1, wherein said germanium-containing gas is selected from germane, digermane, germanium tetrachloride, and germanium tetrafluoride.

13. The method of claim 1, wherein said at least one precursor gas includes a silicon-containing precursor gas.

14. The method of claim 13, wherein said at least one precursor gas further includes a germanium-containing precursor gas or a carbon-containing precursor gas.

15. The method of claim 1, further comprising in-situ doping said deposited semiconductor material with p-type dopant atoms or n-type dopant atoms by flowing a dopant gas concurrently with a flow of said at least one precursor gas.

16. The method of claim 1, wherein said at least one precursor gas includes precursor gases for a compound semiconductor material.

17. The method of claim 1, wherein said semiconductor material is deposited on said substrate during each of said at least one deposition step within a process chamber at a pressure selected from a pressure range from 3 Torr to 300 Torr.

18. The method of claim 1, wherein said deposited semiconductor material is etched during each of said at least one etch step within a process chamber at a pressure selected from a pressure range from 1 Torr to 300 Torr.
